(19) United States
(12) Patent Application Publication
(10) Pub. No.: US 2009/0009210 A1
(43) Pub. Date: Jan. 8, 2009

(54) Scan-Testable Logic Circuit

(75) Inventors: Frank Johan Te Beest, Eindhoven (NL); Adrianus Marinus Gerardus Peeters, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/572,998

(22) PCT Filed: Jul. 26, 2005
(86) PCT No.: PCT/IB05/52506

§ 371 Date: Jan. 31, 2007

(30) Foreign Application Priority Data
Aug. 3, 2004 (EP) 04103730.0

(51) Int. Cl. H03K 19/00

(52) U.S. Cl. 326/16

(57) ABSTRACT

Logic circuit comprising—at least a first combinational logic circuit 42—a first data latch 44 having a data input d and a data output q, said data output q being connected to an input of said first combinational logic circuit 42,—a second scannable data latch 43 having an output q connected to the data input d of said first data latch 44 and—a third scannable data latch 47 having an input d connected to an output of said first combinational logic circuit 42, wherein the second scannable data latch 43 is adapted to being driven by a first clock clk1, the first data latch 44 and the third scannable data latch 47 are adapted to being driven by a second clock clk2, the first and second clocks clk1 and clk2 being non-overlapping clock signals.

The present invention relates to a scan-testable logic circuit and a method for testing the scan-testable logic circuit

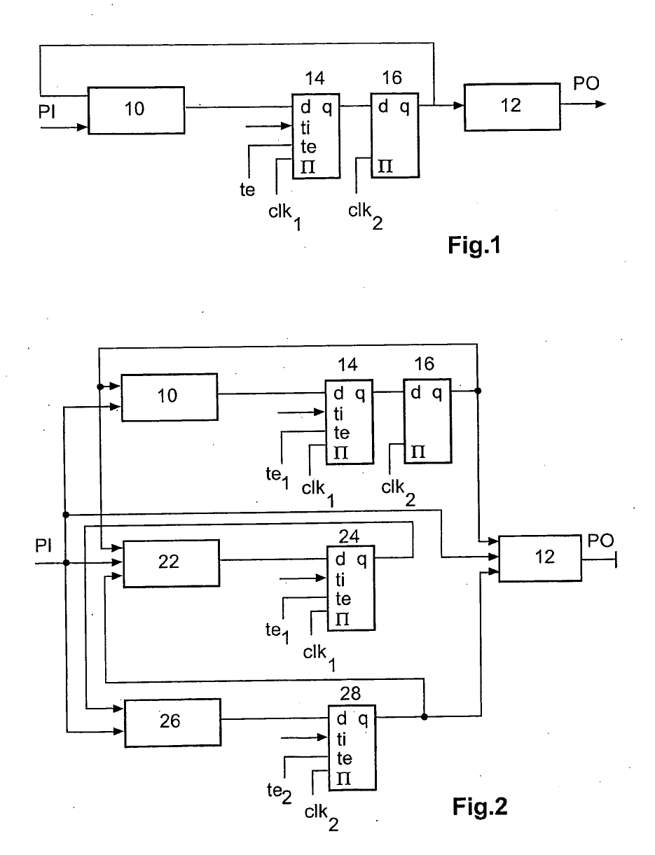

U.S. Pat. No. 3,761,695 originally discloses the conventional circuit design according to the LSSD-design rules as depicted in FIG. 1. LSSD stands for Level Sensitive Scan Design. The circuit comprises two different kinds of latches 14 and 16. Latch 16 is regular d-latch. D-latches have an input d (data input) and an output q (data output). Furthermore, the d-latch 16 has a clock input termed clk2 in FIG. 1. As long as the clock input clk2 is low, the output q does not assume the value at the input d of the d-latch 16 in FIG. 1. The latch is “opaque” and the output q from the latch 16 remains unchanged. The d-latch becomes “transparent”, if the clock input clk2 is in a high state. In this case, the output q assumes the value at the input d of the d-latch. In this way the transfer of information via the d-latch is synchronized with the level of clock clk2.

The latch 14 in FIG. 1 is a scannable or testable latch. This means that information may be introduced externally into said latch for testing. The latch 14 also has a d-input (data input), an output q and a clock input termed clk1 in FIG. 1. Additionally, the latch 14 comprises an input ti and an input te. te stands for test enable and ti stands for test input. As long as the test enable input te to the scannable latch is in a low state, the latch 14 in FIG. 1 functions exactly like the latch 16 in FIG. 1. The input ti to the latch 14 has no influence on the output q of latch 14 as long as the test enable input te is low. Once the test enable te is in a high state, then only the test input ti may be latched to the output q. In this way, information may be introduced into latch 14 from an external source.

Reference signs 10 and 12 in FIG. 1 designate a combinational logic circuit. PI signifies the information input to the combinational logic circuit 10 and reference sign PO signifies the information output form the combinational logic circuit 12 in FIG. 1. Clocks clk1 and clk2 in FIG. 1 are non-overlapping clocks. This means that clock 1 is high only if clock 2 is low and vice versa. The latches 14 and 16 in FIG. 1 represent a shift register. The information is shifted through the latches 14 and 16 sequentially.

Reference signs 10 and 12 in FIG. 1 represent combinational logic circuits. A combinational logic element is a device having at least one output channel and one or more input channels, all characterized by discrete states, such that at any instant the state of each output channel is completely determined by the states of the input channels of the same instant. In contrast, a sequential logic circuit is a circuit design that employs one or more inputs and one or more outputs, whose states are related by defined rules, which depend, in part, on previous states. The outputs of sequential circuits depend on current inputs and previous inputs. By feeding back the output of a combinational logic circuit to its input, the combinational logic circuit is turned into a sequential circuit. The state of the output depends on the previous state of the inputs.

The functional units of a logical system are formed of both combinational as well as sequential circuits. Although computational procedures are available for computing tests and test patterns for combinational circuits, such procedures are difficult to apply for a sequential circuit and no general solution has yet been found to the problem of generating test patterns for complicated sequential logic circuits. Consequently, it is necessary that all sequential circuitry in a logic system be effectively reduced to combinational circuitry to effectuate a test procedure on a network of circuits. This is done conventionally by inserting the latches 14 and 16 in the circuit of FIG. 1. In order to test the combinational logic circuit 10 in FIG. 1, the input to the combinational logic circuit must been known at a predetermined point in time and the output must be measured at the same time. The input of the combinational logic circuit 10 comprises the inputs PI, which may be defined externally as well as the input provided by the feedback loop. The feedback input is defined by shifting a test input via latch 14 into latch 16. When clock 2 is low and clock 1 is high, then the output of latch 16 is input to the combinational logic circuit 10. In this instance, the test enable input te of latch 14 is turned low, such that the output of the combinational logic circuit is input into latch 14. The output of the latch 14 represents the response of the combinational logic 10 to the predetermined inputs. In this way that combinational logic circuit represents a subsystem, which may be tested. Furthermore, the latches 14 and 16 may be used to define the input to combinational logic circuit 12 at another point in time for testing. The combinational logic circuit 12 does represent a logic subsystem, of which the output can be measured directly at the outputs PO.

The circuit in FIG. 1 represents a level sensitive logic system. A logic system is level sensitive if, and only if, the steady state response to any allowed input state change is independent of the circuit and wire delays within the system. Also, if an input state change involves the changing of more than one input signal, then the response must be independent of the order in which they change. The steady state response is the final value of all logic gate outputs in particular the outputs of internal storage elements such as flip-flops or feedback loops. A level sensitive system is assumed to operate as a result of a sequence of allowed input state changes with sufficient time laps between changes to allow the system to stabilize in the new internal state. The term “allowed input state changes” implicates restrictions to input changes. These restrictions apply almost exclusively to the system clock in the signals.

The circuit of FIG. 1 represents a level sensitive scan design according to the above definition. The clock signals clk1 and clk2 have duration long enough to set the latches 14 and 16. The high phase of the clock signals clk1 and clk2 must be sufficient for changing the values stored in said latches. Furthermore, the time interval before the high to low transition of the clock signals clk1 and clk2 must be sufficient to allow all latch changes to travel through the combinational logic circuits activated by the feedback connection. Such an operation meets the requirements for a level sensitive system and assures a minimum dependency on circuit parameters.

The circuit of FIG. 1 is an example of level sensitive logic system. The circuit of FIG. 1 is a sequential logic system. The sequential logic circuit of FIG. 1 is designed in such a way, that it may be tested by testing its combinational logic subsystems using automatically generated test pattern for combinational logic networks. Thus, the problem of sequential test generation may be reduced to a combinational test-generating problem. A sequential logic circuit, which may be tested using combinational patterns only, may be designed by adhering to the following rules.

The inputs to a combinational subsystem of the circuit must be either directly controlled by the data input PI or it must be controlled by the output of a shift register (srl) composed of latches 14 and 16 as in FIG. 1. The d-latch of the shift register is connected to the input of the combinational subsystem. Furthermore, the output of the combinational logic subsystem must be either directly observable or observable from the input of a shift register composed of the latches 14 and 16 as in FIG. 1. In case of a closed loop, the shift register may be used for both controlling the input and observing the output of the combinational network as shown in FIG. 1. In this way, the combinational logic systems may be tested independently of each other.

FIG. 2 shows a conventional L1L2-circuit. This circuit design is originally disclosed in U.S. Pat. No. 4,293,919. The circuit is designed in such a way that it may be tested using combinational test pattern only. The design differs from the design according to the above rules for LSSD-circuits. The circuit of FIG. 2 comprises three combinational logic circuits 10, 22 and 26. The combinational logic circuit 10 has an output, which is connected via latches 14 and 16 with its input. Therefore, combinational circuit 10, latches 14, 16 as well as combinational circuit 12 correspond to the circuit configuration of FIG. 1. The circuit of FIG. 2 differs from the circuit of FIG. 1 by the combinational logic circuits 22 and 26. The output of the combinational logic circuit 22 is connected to the input of combinational logic circuit 26 via latch 24. The output of combinational logic circuit 26 is connected to the input of the combinational logic circuit 22 via the latch 28. Please note, that the new bottom part of the circuit of FIG. 2 constitutes a closed loop. The combinational logic circuits 22 and 26 are part of the closed loop. Let us consider, how the circuit of FIG. 2 would have to be modified, in order to correspond to the LSSD-design rules explained above.

Due to the closed loop containing the combinational logic circuit 22 and 26, the lower part of the circuit of FIG. 2 constitutes a sequential logic circuit. According to the LS SD-design rules, such a sequential circuit is made testable by inserting shift register latches in the closed loop. The shift register of FIG. 1 must be connected to the output of the combinational logic circuit 22. The shift register is used to control an input of the combinational logic circuit 26. The other input of the combinational logic circuit 26 may be controlled by input PI. Furthermore, a corresponding latch pair must observe the output of the combinational logic circuit 26 as well as control the feedback input to the combinational logic circuit 22. Consequently, the circuit in FIG. 2 would comprise a pair of latches 14 and 16 as in FIG. 1 in place of the latches 24 and 28, respectively. The circuit of FIG. 2 is obviously less complex, since it comprises fewer latches than required by the LSSD-design rules. The circuit comprises two scannable latches 24 and 28, which are driven with different clocks clk1 and clk2.

The combinational logic circuit 26 may be tested in the following way. The input to the combinational logic circuit 26 is controlled directly by the input PI as well as the output of latch 24. The output of latch 24 may be controlled externally by the test input ti and the test enable input of latch 24. The input is changed during a high phase of the clock clk1. The output of the combinational logic circuit 26 is input to the latch 28 during the immediately following high phase of the clock clk2 in the latch 28. In this instance, the test enable signal of latch 28 is low. In this way, the reaction of the combinational logic circuit 26 to a predetermined input may be tested. The test of the combinational logic circuit 22 works correspondingly. In this case, the latches 28 and 24 change roles. Latch 28 is used for controlling the input of the combinational logic circuit 22 and latch 24 receives the output form the combinational logic circuit 22. Additionally, the input to the combinational logic circuit 22 is defined by the output of the latch 16 in FIG. 2.

Please note, that the latch 16 in FIG. 2 is not redundant. The combinational logic circuit 10 in FIG. 2 may not be tested using the latch 14 only. The reason for this is that the output of the combinational logic circuit 10 drives the input of the combinational logic circuit 10. If the input of the combinational logic circuit is defined by latch 14 only, then the following output of the circuit 10 may not be input to latch 14 without immediately changing the input to circuit 10. If the clock of latch 14 is high, then the input to latch 14 is immediately transferred to its output and consequently drives the input of the logic circuit 10. The input of the logic circuit 10 would not have a predetermined state during testing.

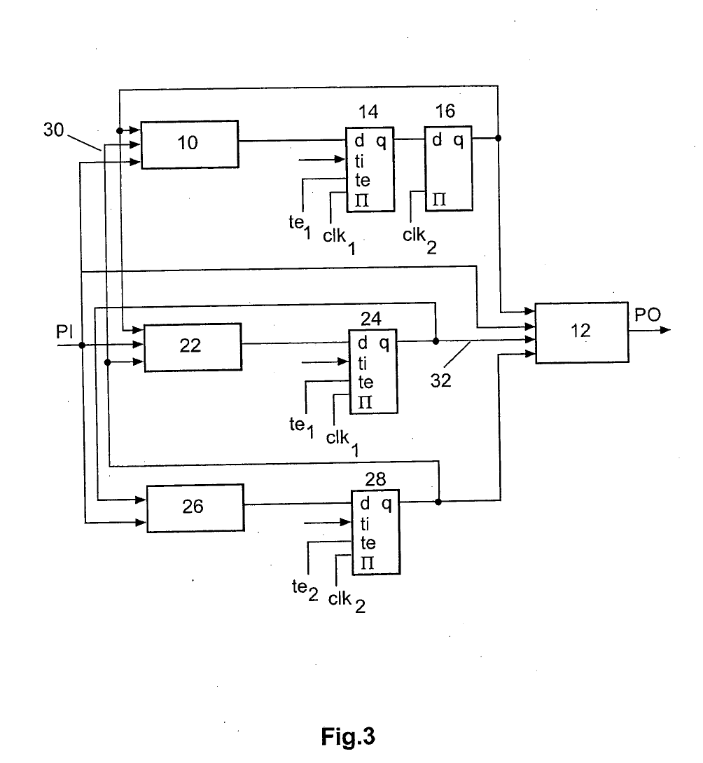

FIG. 3 shows a modification of FIG. 2. The same components in FIGS. 2 and 3 are depicted by the same reference numerals. The only difference compared to the circuit of FIG. 2 lies in the additional connections 32 and 30 contained in the circuit of FIG. 3. The combinational logic circuit 10 in FIG. 3 has three inputs. The additional input 30 is driven by the output of latch 28. Latch 28 is scannable. Consequently, the input to the combinational logic circuit 10 may be controlled by the latches 28, 16 and by the input PI during a high phase of the clock clk2.

In order to reduce testing of a logic circuit to the testing of a combinational logic circuit, the input and output signals of each combinational logic circuit constituting the tested logic circuit must be controllable during a predetermined time period. The circuit as a whole is tested by testing the combinational logic circuits, which are constituents of the logic circuit. The L1L2-design rules for a logic circuit design for combinational testing may be summarized in the following way.

In case a combinational logic circuit comprises inputs and/or outputs, which may not be controlled externally, these inputs and outputs must be connected to a latch. The latches controlling the inputs and the latches receiving the outputs of a particular combinational logic circuit must be driven by different, non-overlapping clocks. Two adjacent latches must be driven by different, non-overlapping clocks. The following latch (slave latch) may be a non-scannable data latch (d-latch). Otherwise, the latches must be scannable latches. For example in FIG. 1 latch 16 is driven by latch 14. Therefore, latch 16 may be simple non-scannable data latch (d-latch).

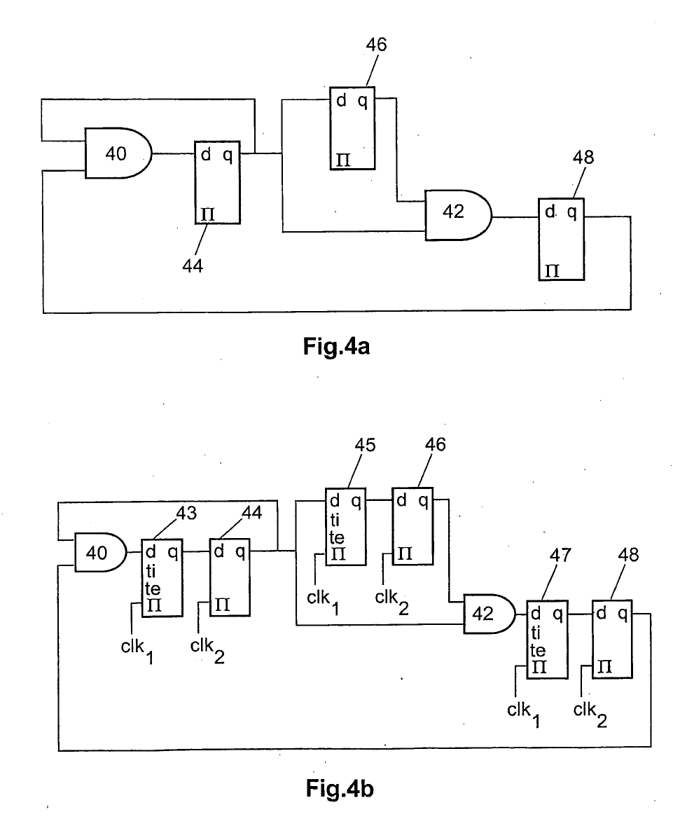

FIG. 4a shows an example circuit that has been made scan testable. The circuit of FIG. 4a comprises two combinational logic circuits 40 and 42. Both logic circuits have two inputs and a single output. Furthermore, the circuit of FIG. 4a has three non-scannable data latches 44, 46 and 48. For this discussion it is assumed that the clock signals of these latches has not been selected yet and is not dictated by the functional operation of the circuit. The output of the combinational logic circuit 40 is fed to the input of the combinational logic circuit 40 via the latch 44. The second input of the combinational logic circuit 40 is controlled by the data latch 48. In order to make the combinational logic circuit 40 scan-testable according to the above mentioned L1L2-design rules, the inputs and output of the combinational logic circuit must be controllable for a predetermined period of time. The closed loop in FIG. 4a around latch 44 and combinational logic circuit 40 corresponds to the closed loop present in FIG. 1 and the upper part of FIG. 2. According to the L1L2-design rules two latches have to be present in this closed loop. Therefore, the scannable latch 43 is inserted to the circuit of FIG. 4b. Latches 43 and 44 are driven with different non-overlapping clock signals clock 1 and clock 2. While the output of the combinational logic circuit 40 is input to the latch 43 during a high phase of clock 1, the input to the combinational logic circuit 40 driven by the output of latch 44 remains unchanged (clock 2 is low). The output of the combinational logic circuit 40 may be recorded in latch 43, whilst the upper input of the combinational logic circuit 40 has a defined value. The lower input of the combinational logic circuit 40 may be driven by a scannable latch 47 in FIG. 4b.

A pair of latches 47 and 48 must be used in this case as shown in FIG. 4b. The reason is, that according to the above design rules, no two latches may follow each other, which are clocked by the same clock. If only latch 47 were present in the lower line of FIG. 4b, then this requirement could not be fullfilled. If latch 47 were clocked with clk1, then latches 47 and 43 would have the same clock signal. This is forbidden. If on the other hand latch 47 had the clock 2, then latches 44 and 47 would have the same clock signal. This is also forbidden. Therefore, a second latch 48 must be inserted in the circuit as shown in FIG. 4b.

In order to test the combinational logic circuit 42, the inputs and outputs of the circuit have to be controlled during a predetermined period of time. The lower input of combinational logic circuit 42 may be controlled by latch 44 which is also used for testing combinational logic circuit 40. The output of combinational logic circuit 42 may be observed with latch 47, which is also used for controlling the input of latch 48. Only the upper input of combinational logic circuit 42 remains to be controlled for testing. To this end a scannable latch 45 would be inserted into the circuit of FIG. 4b. But also in this case a latch pair 45 and 46 must be used in the circuit. The reason is, that a single latch is adjacent to latch 44 driven with clock 2 and latch 47 driven with clock 1. Consequently, the L1L2-design rules require a circuit configuration as shown in FIG. 4b.

In this particular example, L1L2-testing has no advantage over regular LSSD-testing. In general, the advantages that can be obtained by L1L2-testing become higher, when the circuit contains fewer small feedback loops and contains more pipeline structures. In particular handshake control circuits contain typically many such small feedback loops. This reduces the impact that the L1L2-optimization has over the LSSD-optimization. The example of FIG. 4b shows, that even the L1L2-design rules may result in a circuit design having a considerable amount of additional latches. In order to make the circuit of FIG. 4a testable according to the L1L2-design rules, three additional latches had to be introduced. Therefore, the area and power consumption of the circuit are high and the speed is relatively low.

It is object of the present invention to provide logic circuit, which is fast, smaller and has a reduced power consumption than conventional scan-testable circuits. Furthermore, it is object to provide a test method which allows the scan-testing of the logic circuit according to the invention.

The object is solved by the logic circuit according to the appended claim 1. The logic circuit according to the invention comprises a first combinational logic circuit. The logic circuit further comprises a first data latch having a data input and a data output. The data output of the first data latch is connected to an input of the first combinational logic circuit. The logic circuit further comprises a second, scannable data latch having an output, which is connected to the data input of the first data latch. The first and second data latches form a pair of latches (for example like the latches in FIG. 1). The logic circuit further comprises a third scannable data latch having an input, which is connected to the output of the first combinational logic circuit. The second scannable data latch is adapted to being driven by a first clock. The first data latches as well as the third scannable data latch are adapted to being driven by a second clock. The first and second clocks are non-overlapping clock signals. Please note, that this circuit does not conform with the L1L2-design rules. The first and the third data latch are driven by the same clock signal, although they are adjacent to each other. This is forbidden according to the second L1L2-design rules given above. Nevertheless the logic circuit according to the invention is scan-testable.

The logic circuit according to the invention may be tested in the following way: in the beginning, test data is input into the second scannable data latch. This is done during a high phase of the first clock. The data is input to the second scannable data latch. In this instance a test enable input of the second scannable data latch is driven such, that the second scannable data latch receives the data from the test input. Once the first clock is low, the test data is retrievable from the output of the second data latch. Since clocks 1 and 2 are non-overlapping, the second clock has a high phase during the low phase of the first clock. In this instance, the first data latch of the logic circuit is transparent. Therefore, the test data at the output of the second data latch is immediately transferred to the input of the first combinational logic circuit to be tested. The first data latch is redundant. It does not distrub testing, although the latch will represent a logic delay. The first combinational logic circuit is driven by the second scannable data latch during an adjacent high phase of the second clock signal. Simultaneously, i.e. during the adjacent high phase of the second clock signal, the output of the first combinational logic circuit to be tested may be stored in the third scannable data latch.

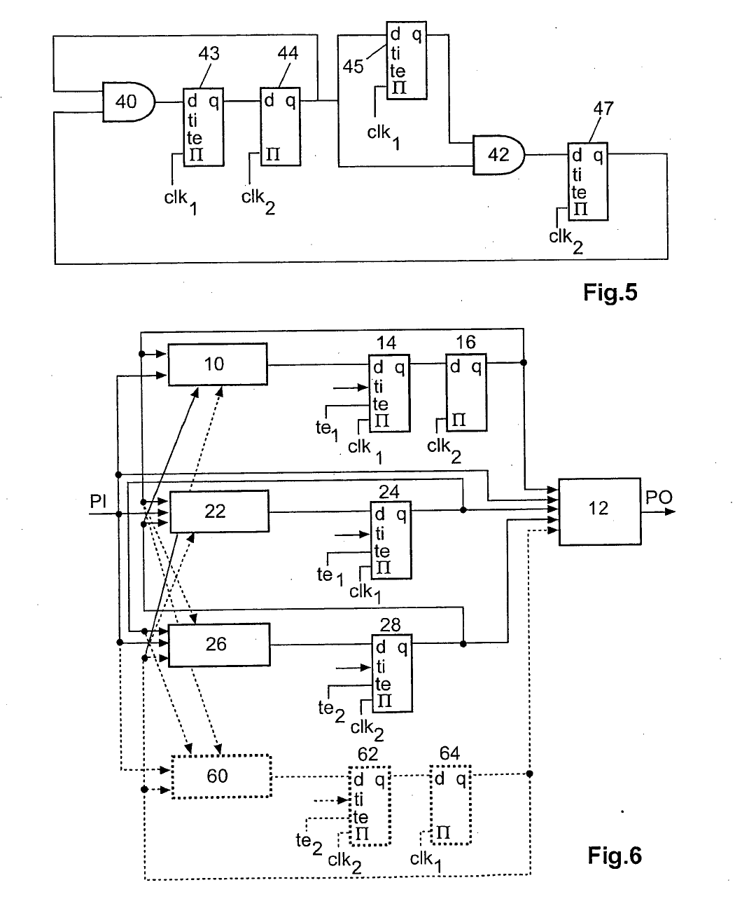

Although the first data latch is redundant during testing of the first combinational logic circuit, the provision of this latch may enable the reduction of the number of latches needed for testing. This is true in particular for the circuit of FIG. 4b. In particular, if the first and second latch are part of a closed loop containing a single additional combinational logic circuit, then the additional second combinational logic circuit may only be tested using both the first and the second data latch. The first data latch is necessary for testing the second combinational logic circuit. The first data latch is redundant, when the first combinational logic circuit is tested. Since both combinational logic circuits need to be tested, the first data latch is a necessary component in the circuit. But the latches 46 and 48 may be deleted from the circuit in FIG. 4b, if the latch 47 is clocked with clock 2 as in FIG. 5. Clocking latch 47 with clock 2 is only allowed if the clock signal is not dictated by the functional requirement of the circuit. For handshake circuits this is in general not the case and the proposed method is valid. For conventional synchronous circuits however, often the clock signal is already determined and the proposed method cannot be used.

The circuit design according to claim 1 allows more dummy latches to be removed from the circuit. This is especially relevant for handshake circuits, which are known for their high number of short feedback loops. The circuit design and test method according to the present invention may be implemented in handshake circuits. The handshake circuit design is increasingly relevant for digital Ics. The main features of this technology are its low power and low electro magnetic emission characteristics.

The optimization due to the circuit design according to the present invention may be used to reduce the number of slave latches (non-scannable latches) in latch-based circuits. This will reduce the circuit area, increase its speed and also reduce the power consumption. The benefit is the largest for circuits that contain many small feedback loops.

Preferred embodiments of the present invention are described with reference to the accompanied drawings below.

FIG. 1 shows a conventional logic circuit which conforms with the level sensitive scan design (LSSD).

FIG. 2 shows a conventional logic circuit, which agrees with the L1L2-scan design.

FIG. 3 is a further conventional logic circuit, which conforms with the conventional L1L2-scan design rules.

FIG. 4a is a conventional logic circuit, which may not be tested using conventional LSSD- or L1L2-scan design tests.

FIG. 4b is a modification of FIG. 4a, which conforms with the LSSD- as well as the L1L2-scan design.

FIG. 5 shows a first embodiment of the logic circuit according to the present invention.

FIG. 6 shows a second embodiment of the logic circuit according to the present invention.

FIG. 7a shows conventional circuit for generating clock signals.

FIG. 7b shows the clock signals generated by this circuit.

FIG. 8a schematically shows a portion of a scan testable circuit according to the invention.

FIG. 8b shows the signals occurring in this circuit portion.

FIG. 9a shows an improved circuit for generating clock signals.

FIG. 9b shows the clock signals generated by this circuit.

FIG. 10 shows a further improved circuit for generating clock signals.

The embodiment of the present invention shown in FIG. 5 constitutes a scan-testable modification of the circuit of FIG. 4a.

Please note that the circuit of FIG. 5 comprises only four latches 43, 44, 45 and 47, whereas the scan-testable circuit according to the state of the art in FIG. 4b comprises six latches. The crucial difference between the circuit of FIG. 5 and the circuit of FIG. 4b lies in the configuration of latches 43, 44, 47 as well as the combinational logic circuit 42. The only difference between the arrangement of these components lies in the clocking of latch 47. Latch 47 in FIG. 5 is clocked with clock 2, whereas latch 47 in FIG. 4b is clocked with clock 1. Latch 47 may not be controlled with the same clock as latch 44 according to the L1L2-design rules of the state of the art. According to the logic circuit of the present invention, such a configuration is explicitly allowed, if clocks clk1 and clk2 are non-overlapping clocks. The latch 44 is redundant during testing of the combinational logic circuit 42. The output of latch 43 clocked by clock 1 is transferred to the input of the combinational logic circuit 42 during a high phase of clock 2, since the latch 44 is transparent during a high phase of clock 2. Therefore, the lower input of the logic gate 42 may be defined conveniently using the scannable latch 43. The upper input of the combinational logic circuit 42 in FIG. 5b is connected to a further scannable latch 45. The output of latch 45 during a high phase of clock 2 is equal to the information stored in the scannable latch 45. Therefore, the data input to the combinational logic circuit 42 may be defined for testing during a high phase of clock 2. The output of the combinational logic circuit during a high phase of clock 2 is input to the scannable latch 47 during the high phase of clock 2. This is accomplished, if the test enable input (te) of the scannable latch 47 disables the test input (ti) and enables the usual data input d of the scannable latch 47. In this way, the combinational logic circuit 42 may be tested according to the present invention.

Please note that the circuit of FIG. 5 otherwise fulfills the conventional L1L2-scan design rules. The closed loop consisting of the combinational logic circuit 40, the latch 43 as well as the latch 44 in FIG. 5 is an implementation of the circuit of FIG. 1. The closed loop consisting of the combinational logic circuit 40, latches 43, 44 and 45, combinational logic circuit 42 as well as latch 47 conforms with the L1L2-scan design rules. Neighboring latches are always clocked with a different clock. No two adjacent latches in the closed circuit are clocked with the same clock.

FIG. 6 shows a second embodiment of the present invention. The circuit of FIG. 6 is composed of two parts. The first part comprises all the components connected with each other by drawn through lines. This part of the circuit corresponds exactly to the conventional circuit of FIG. 3. The second part of the circuit comprises those parts, which are connected with each other with dashed lines. These connections are prohibited according to the conventional design rules, but they are allowed for the circuit of the present invention.

In FIG. 3 the output of latch 16 is connected to the combinational logic circuits 10 and 22, but the output of latch 16 is not connected to the combinational logic circuit 26. The reason for this is, that latch 28 and 16 are driven be the same clock 2. If latch 16 were connected with the input of the combinational logic circuit 26, then latches 16 and 18 would be considered adjacent to each other. According to the conventional design rules adjacent latches may not be clocked with the same clock. On the other hand in FIG. 6 the output of latch 16 is connected with the input of combinational logic circuit 26. The present invention explicitly allows such a connection. The configuration of latch 14, 16, combinational logic circuit 26 and latch 28 in FIG. 6 corresponds to the configuration of latches 43, 44, combinational logic circuit 42 and latch 47 in FIG. 5. Additionally, a combinational logic circuit 60, a latch 62 and a latch 64 are provided in the circuit of FIG. 6. The configuration of these new components corresponds to the configuration of the combinational logic circuit 10, the latch 14 and the latch 16 in the upper part of the circuit as shown in FIG. 6 with one exception: latch 62 corresponding to latch 14 is clocked with clock 2 instead of clock 1 and latch 64 corresponding to latch 16 is clocked with clock 1 instead of clock 2. The output of latch 64 is connected to the input of every combinational logic circuit (10, 22, 26 and 60). Also, the output of latch 16 is connected to the input of each combinational logic circuit in FIG. 6. According to the invention the output of a pair of latches such as latch pair 14, 16 or latch pair 62, 64 may be connected to the input of a combinational logic circuit irrespective of the latches connected to the output of these combinational logic circuits. As can be seen in FIG. 6, the logic circuit of the present invention allows for many more connections than the testable circuits according to the state of the art in FIG. 3.

In FIG. 7a, a conventional circuit to generate non-overlapping clock signals is shown. Such a circuit is known for example from Charles L. Seitz. System timing. In Carver A. Mead and Lynn A. Conway, editors, Introduction to VLSI Systems, chapter 7. Addison-Wesley, 1980

The circuit is based on a pair of cross-coupled NOR gates 71, 72, combined with delay elements (d1 and d2) that determine the duration of the non-overlapping period. The circuit is controlled by an external reference clock, which determines the clock period.

The rising edges of latch-clock signals clk1 and clk2 are delayed by the delay elements d₁, d₂; the falling edges directly follow the reference clock. The delay introduced by the delay elements must be a fraction of the clock frequency, in practice below 25% of the clock period.

The method of testing a logic circuit according to the invention allows for redundant slave latches to be present between two master latches that are operated on different clocks. The slave latch 85 must be clocked by the same clock clk1 as the receiving master latch 87 as illustrated in FIG. 8a. This slave latch 85 is redundant for this path, from master latch 84 to master latch 87, but its presence can be required for the test of a different path through the circuit. As shown, the slave latch can drive master latches clocked on clk₁ as well as master latches clocked on clk₂, allowing a partitioning in clk₁ and clk₂ that minimizes the total number of slave latches. As long as all scan elements are latches, the system is guaranteed to work. However, if the receiving master latch is a scan C-element as in FIG. 8, an additional requirement has to be met. The requirement is that the input of the C-element 87 has to be stable and remain stable during the entire time that its clock input is high. During this time, the C-element 87 behaves as a normal non-scan C-element and the effect of changes on its inputs immediately updates the internal state of the element.

The problem is illustrated in FIG. 8b. The circuit of FIG. 8a is initialized via the scan chain (not shown in the figure), such that: x=0, y=c=1 and z=0. For correct operation, the C-element must see the value of x on its input c at the time when clk₁ becomes active. The correct behavior would thus be to first propagate x to c, resulting in c=0, and then to enable the clock of the C-element 87 and since d=1 and c=0, z should remain low. The actual behavior of the circuit in FIG. 8b however is to clock the slave latch 85 and the C-element 87 simultaneously. In this case, the C-element 87 is enabled while c is still high, therefore the output z will also become high. When after the logic delay c will go low, the output will remain high, because the internal state of the C-element 87 was updated. The solution to this problem is to separate the clock signals used for the slave latches from the clock signals used for the scan C-elements. The rising edge of the clock for the C-elements has to be delayed with respect to the rising edge of the clock for the slave latch. This will allow signals to propagate through the slave latch to the input of the scan C-element while the clock for the C-elements is still inactive. A practical embodiment of a suitable clock generator for this purpose is shown in FIG. 9a. A timing chart is shown in FIG. 9b.

Instead of adding another set of delay elements to achieve this behavior, the design of FIG. 9a reuses the already present delay elements d₁, d₂. The same delay elements d₁, d₂ that are used to create the non-overlapping period are also used to obtain the further delayed clock signals clk_{1c}, clk_{2c} for the C-elements. With respect to the active edge of the reference clock, the normal clock signals clk₁, clk₂ are delayed by one delay element and the clocks clk_{c1}, clk_{c2} for the c-elements are delayed by both delay elements. With this clock generator, the circuit will operate correctly as long as the logic delay is smaller than the delay of a delay element in the clock generator.

The new clocks for the C-elements are generated by AND gates 93, 94 having one input connected to the original clock and the other input to a delayed version of this clock. Only rising edges are delayed. The falling edges remain the same, since they are not allowed to extend beyond the original falling edge, which would reduce the non-overlapping period of the clock signals (for example between clk_{2C} and clk₁).

In order to enable use in handshake circuits, it is desirable that two more functions are supported in the circuit. Both can be easily integrated in the proposed clock generator as is illustrated in FIG. 10.

Support for asynchronous mode is accomplished by making both clock signals active. A new control signal “TestMode” is added which controls two AND gates 107, 108 that are used to force both the L1 and the L2 parts of the circuit high when “TestMode” is low, (indicating asynchronous circuit operation). The AND 107, 108 gates for the test mode 10 can be combined with the cross-coupled NOR gates 101, 102.

Integrated de-multiplexing. The scan C-elements that are used require LSSD-style clock signals. This means that two separate clocks are used, depending on whether the scan input (the clocks clk_{1cs}, clk_{2cs}) or the normal data input (the clocks clk_{1cen} and clk_{2cen}) has to be captured by the element.

The AND gates 103, 104 of the de-multiplexer that produce the normal mode enable signals clk_{1cen}, and clk_{2cen}, are combined with the AND gates for the C-element clock into 3-input AND gates. The AND gates 105, 106 that produce the other two clock signals clk_{1cs} and clk_{2cs} used to scan shifting do not need a third input, since during scan shift the problem described in Section 3 can never occur.

It is remarked that the scope of protection of the invention is not restricted to the embodiments described herein. Neither is the scope of protection of the invention restricted by the reference numerals in the claims. The word ‘comprising’ does not exclude other parts than those mentioned in a claim. The word ‘a(n)’ preceding an element does not exclude a plurality of those elements. The invention resides in each new feature or combination of features.

1. A logic circuit comprising:
at least a first combinational logic circuit;
a first data latch having a data input and a data output, said data output being connected to an input of said first combinational logic circuit;
a second scannable data latch having an output connected to the data input of said first data latch; and
a third scannable data latch having an input connected to an output of said first combinational logic circuit,
wherein the second scannable data latch is adapted to being driven by a first clock, the first data latch and the third scannable data latch are adapted to being driven by a second clock, the first and second clocks being non-overlapping clock signals.

2. The logic circuit of claim 1, wherein the first data latch connected to the input of the combinational logic circuit is a non-scannable data latch.

3. The logic circuit of claim 2, wherein the output of the first data latch is connected to an input of a second combinational logic circuit and the second combinational logic circuit has an output connected to a data input of the second scannable data latch.

4. The logic circuit of claim 1, including a fourth data latch having an output connected to an input of the first combinational logic circuit, wherein the fourth data latch is adapted to be driven by the first clock signal.

5. The logic circuit of claim 4, wherein a data input of the fourth data latch is connected to the data output of the first data latch.

6. A method for testing the first combinational logic circuit of the logic circuit of claim 1, comprising:
inputting test data via a test input into the second scannable data latch during a high phase of the first clock;
transferring the test data to the first combinational logic circuit during an ensuing high phase of the second clock;
storing the output of the first combinational logic circuit in the third scannable data latch during the ensuing high phase of the second clock; and
reading out information stored in the third scannable data latch.
